(19) United States
(12) Patent Application Publication
(10) Pub. No.: US 2021/0391218 A1
(43) Pub. Date: Dec. 16, 2021

(54) SEMICONDUCTOR DEVICE MANUFACTURING BY THINNING AND DICING

(71) Applicant: Infineon Technologies AG, Neubiberg (DE)

(72) Inventors: Felix Johannes Heinrich Ernst, Villach (AT); Bernhard Goller, Villach (AT); Iris Moder, Villach (AT); Ingo Muri, Villach (AT)

(21) Appl. No.: 17/343,885

(22) Filed: Jun. 10, 2021

(30) Foreign Application Priority Data
Jun. 15, 2020 (DE) 102020115687.1

(51) Int. Cl. H01L 21/78; H01L 21/306; H01L 21/225; H01L 29/06; H01L 23/14

(52) U.S. Cl. CPC H01L 21/78; H01L 21/30608; H01L 23/142; H01L 29/0657; H01L 21/225

(57) ABSTRACT

A method of manufacturing a semiconductor device is described. A semiconductor substrate is provided. The semiconductor substrate includes a semiconductor substrate layer and a semiconductor device layer. The method includes transforming areas of the semiconductor device layer into dicing areas which can be removed by etching, and removing the semiconductor substrate layer and the dicing areas by using etching.

### TECHNICAL FIELD

This disclosure relates generally to the field of manufacturing semiconductor devices, and in particular to the field of wafer thinning and wafer dicing.

### BACKGROUND

Semiconductor devices are manufactured by dicing a semiconductor wafer into a plurality of semiconductor chips (also termed dies in the art). Dicing can be carried out by various techniques, e.g. sawing, laser cutting or etching. These techniques are known to show different characteristics in terms of process time, edge damage risks, loss of semiconductor material, etc.

Another aspect of semiconductor device manufacturing aims at providing thin semiconductor chips. The production of thin semiconductor chips is challenging in view of semiconductor wafer thinning, semiconductor wafer handling and semiconductor wafer dicing. Further, the functionality and reliability of products containing thin semiconductor chips may sensitively be dependent on the total thickness variation (TTV) of the semiconductor chips. Hence, a high evenness during wafer thinning should be achievable.

### SUMMARY

According to an aspect of the disclosure, a method of manufacturing a semiconductor device is described. The method comprises providing a semiconductor substrate. The semiconductor substrate comprises a semiconductor substrate layer and a semiconductor device layer. The method further comprises transforming areas of the semiconductor device layer into dicing areas which can be removed by etching, and removing the semiconductor substrate layer and the dicing areas by using etching.

According to an aspect of the disclosure, a semiconductor device includes a semiconductor device chip. The semiconductor device chip comprises a semiconductor device layer comprising an integrated device, wherein a dicing edge of the semiconductor device layer has been formed by dopant-selective chemical etching.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other and/or can be selectively omitted if not described to be necessarily required. Embodiments are depicted in the drawings and are exemplarily detailed in the description which follows.

FIG. 1A is a schematic cross-sectional view of an exemplary semiconductor substrate including a semiconductor substrate layer and a semiconductor device layer.

FIG. 1B is a schematic cross-sectional view of the exemplary semiconductor substrate of FIG. 1A at a stage of manufacturing where areas of the semiconductor device layer are transformed into dicing areas.

FIG. 1C is a schematic cross-sectional view of semiconductor device chips generated from the exemplary semiconductor substrate shown in in FIG. 1B by removing the semiconductor substrate layer and the areas of the semiconductor device layer by etching.

FIG. 2A is a schematic cross-sectional view of an exemplary semiconductor substrate including a semiconductor substrate layer, a semiconductor device layer and a semiconductor etch stop layer arranged between the semiconductor substrate layer and the semiconductor device layer.

FIG. 2B is a schematic cross-sectional view of the exemplary semiconductor substrate of FIG. 2A at a stage of manufacturing where areas of the semiconductor device layer and areas of the semiconductor etch stop layer are transformed into dicing areas.

FIG. 2C is a schematic cross-sectional view of semiconductor device chips generated from the exemplary semiconductor substrate shown in FIG. 2B by removing the semiconductor substrate layer and the dicing areas by etching.

FIG. 2D is a schematic cross-sectional view of the semiconductor device chips of FIG. 2C after removal of the etch stop layer from the semiconductor device chips.

FIG. 3A is a schematic cross-sectional view of an exemplary semiconductor substrate including a semiconductor substrate layer, a semiconductor device layer, a semiconductor etch stop layer arranged between the semiconductor substrate layer and the semiconductor device layer and a semiconductor contact layer arranged between the semiconductor etch stop layer and the semiconductor device layer.

FIG. 3B is a schematic cross-sectional view of the exemplary semiconductor substrate of FIG. 3A at a stage of manufacturing where areas of the semiconductor device layer, areas of the semiconductor contact layer and areas of the semiconductor etch stop layer are transformed into dicing areas.

FIG. 3C is a schematic cross-sectional view of semiconductor device chips generated from the exemplary semiconductor substrate shown in FIG. 3B by removing the semiconductor substrate layer and the dicing areas by etching.

FIG. 3D is a schematic cross-sectional view of the semiconductor device chips of FIG. 3C after removal of the etch stop layer from the semiconductor device chips.

FIG. 4A is a schematic cross-sectional view of an exemplary semiconductor substrate in accordance with FIG. 1B, wherein an integrated device is formed in the semiconductor device layer.

FIG. 4B is a schematic cross-sectional view of the exemplary semiconductor substrate of FIG. 4A mounted on a carrier with the semiconductor device layer facing the carrier.

FIG. 4C is a schematic cross-sectional view of the exemplary semiconductor substrate of FIG. 4B after partial removal of the semiconductor substrate layer.

FIG. 4D is a schematic cross-sectional view of semiconductor device chips generated from the exemplary semiconductor substrate shown in FIG. 4C by completely removing the semiconductor substrate layer and the dicing areas between the semiconductor device chips by etching.

FIGS. 5A-5H are schematic cross-sectional views of exemplary stages of manufacturing a semiconductor device by forming high-doped dicing areas in the semiconductor device layer in accordance with a first embodiment and removing the high-doped semiconductor substrate layer and the dicing areas by dopant-selective chemical etching.

FIGS. 6A-6B are schematic cross-sectional views illustrating a variant of the exemplary stages of the first embodiment shown in FIGS. 5A-5H.

FIGS. 7A-7C are schematic cross-sectional views of exemplary stages of manufacturing a semiconductor device by forming high-doped dicing areas in the semiconductor device layer in accordance with a second embodiment and removing the high-doped semiconductor substrate layer and the dicing areas by dopant-selective chemical etching.

FIGS. 8A-8B are schematic cross-sectional views of exemplary stages of a first example of further processing the semiconductor substrate after removing the dicing areas.

FIGS. 9A-9B are schematic cross-sectional views of exemplary stages of a second example of further processing the semiconductor substrate after removing the dicing areas.

FIG. 10 is a schematic cross-sectional view of an exemplary semiconductor device having rounded semiconductor chip edges in a vertical dimension.

FIG. 11 is a plan view of an exemplary semiconductor device having rounded semiconductor chip edges in a horizontal dimension.

### DETAILED DESCRIPTION

It is to be understood that the features of the various exemplary embodiments and examples described herein may be combined with each other, unless specifically noted otherwise.

As used in this specification, the terms “deposited”, “arranged on”, or “applied” or similar terms are not meant to mean that the elements or layers must directly be contacted together; intervening elements or layers may be provided between the “deposited”, “arranged on”, or “applied” elements, respectively. However, in accordance with the disclosure, the above-mentioned and similar terms may, optionally, also have the specific meaning that the elements or layers are directly contacted together, i.e. that no intervening elements or layers are provided between the “deposited”, “arranged on”, or “applied” elements, respectively.

Further, the words “over” or “beneath” with regard to a part, element or material layer formed or located “over” or “beneath” a surface may be used herein to mean that the part, element or material layer be located (e.g. placed, formed, arranged, deposited, etc.) “directly on” or “directly under”, e.g. in direct contact with, the implied surface. The word “over” or “beneath” used with regard to a part, element or material layer formed or located “over” or “beneath” a surface may, however, either be used herein to mean that the part, element or material layer be located (e.g. placed, formed, arranged, deposited, etc.) “indirectly on” or “indirectly under” the implied surface, with one or more additional parts, elements or layers being arranged between the implied surface and the part, element or material layer.

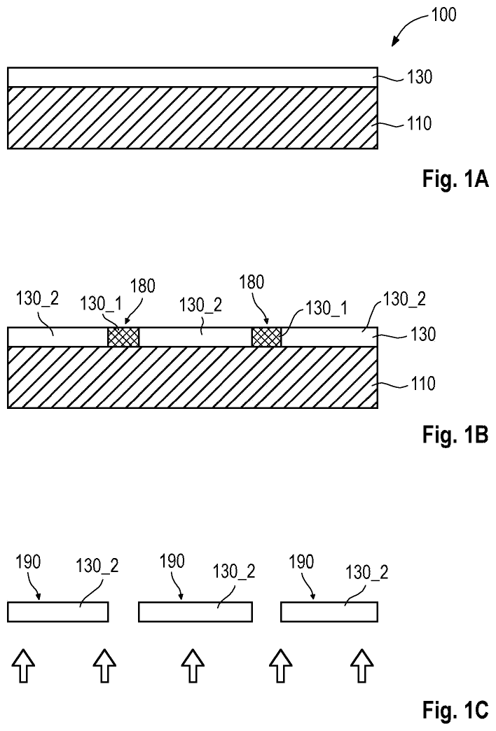

Referring to FIG. 1A, a semiconductor substrate 100 includes a semiconductor substrate layer 110 and a semiconductor device layer 130.

The semiconductor substrate 100 may, e.g., be a semiconductor wafer. The semiconductor substrate 100 may be made of any semiconductor material, e.g. Si, SiC, SiGe, GaAs, GaN, AlGaN, InGaAs, InAlAs, etc. Without loss of generality, the following description exemplarily relates but is not restricted to a semiconductor substrate 100 which is a silicon wafer.

Referring to FIG. 1B, areas 130_1 of the semiconductor device layer 130 are transformed into dicing areas 180 which can be removed by etching. The transformation can be carried out in many ways, e.g. by introducing defects or impurities or dopants into the areas 130_1 of the semiconductor device layer 130. That way, the areas 130_1 are prepared to act as dicing areas 180 in subsequent processing.

The semiconductor device layer 130 may, e.g., be an epitaxial layer.

Integrated devices (not shown) are destined to be formed or already have been formed in areas 130_2 of the semiconductor device layer 130 which are bordered by the transformed areas 130_1 of the semiconductor device layer 130. In other words, the areas 130_2 of the semiconductor device layer 130 may correspond to semiconductor chips to be fabricated by dicing the semiconductor substrate 100 (e.g. wafer) along the dicing areas 180.

Generally, the process of transforming the areas 130_1 of the semiconductor device layer 130 into dicing areas 180 may be carried out before, during or after semiconductor front-end-of-line (FEOL) processing, that is before, during or after the fabrication of the electronic devices (e.g. transistors, capacitors, resistors) in the areas 130_2 of the semiconductor device layer 130.

Referring to FIG. 1C, the semiconductor substrate layer 110 and the dicing areas 180 are removed by using etching. As will be described in greater detail further below, the semiconductor substrate layer 110 may first be partially removed by other processes such as, e.g. grinding. After this optional partial removal the semiconductor substrate layer 110 may then be completely removed by etching. Concurrently with this etching process, the dicing areas 180 are removed by etching.

Etching is indicated by the arrows in FIG. 1C. In the example illustrated in FIGS. 1A-1C, the dicing areas 180 may be identical with the areas 130_1 of the semiconductor device layer 130 which have been transformed to be removed by etching. In other examples the dicing areas 180 may include further layers.

Further, in the examples shown in FIGS. 1A-1C, the semiconductor device layer 130 needs to be resistant to etching. This etch resistance may either be a material-intrinsic property of the semiconductor device layer 130 (e.g. a chemical resistance of the material of the semiconductor device layer 130 to an etchant), as will be illustrated by examples further below, or may be achieved by protecting the semiconductor device layer 130 by an etch stop layer (not shown) arranged between the semiconductor substrate layer 110 and the semiconductor device layer 130.

Referring to FIG. 1C, the removal of the semiconductor substrate layer 110 and the dicing areas 180 separates semiconductor chips 190. Differently put, the process of thinning the semiconductor substrate layer 110 by etching concurrently includes the wafer cutting process.

The chip separation process disclosed herein may be termed a “dicing after grinding” process (as opposed to dicing before grinding (DBG) processes known in the art), since chip separation starts after the termination of grinding (if grinding for partial removal of the semiconductor substrate layer 110 is used). Further, no half-cut dicing into the front side of the semiconductor substrate 100 is needed. Differently put, the front side of the semiconductor substrate 100 (e.g. wafer) may remain untreated for chip separation.

Etching may be performed by chemical etching (as opposed to e.g. anisotropic plasma etching known in the art). As will be detailed further below, the chemical etching process may comprise dopant-selective chemical etching. Chemical etching such as, e.g., dopant-selective chemical etching can be carried out by wet chemical etching. In particular, isotropic etching may be used.

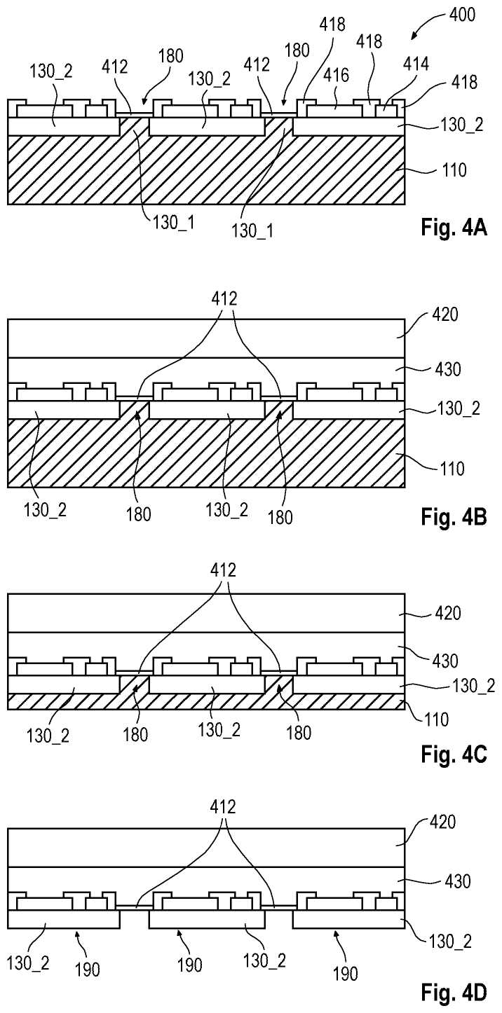

Here and in all other embodiments disclosed herein, the semiconductor device layer 130 may have a small thickness which may, e.g., be equal to or less than 60 μm or 50 μm or 40 μm or 30 μm or 20 μm or 15 μm. The thickness of the semiconductor chips 190 may have the same values. In other words, the disclosure comprises the fabrication of ultra-thin semiconductor wafers and semiconductor chips 190. For these and other reasons, the semiconductor substrate 100 may be mounted to a carrier (see FIG. 4B) with the semiconductor device layer 130 facing the carrier.

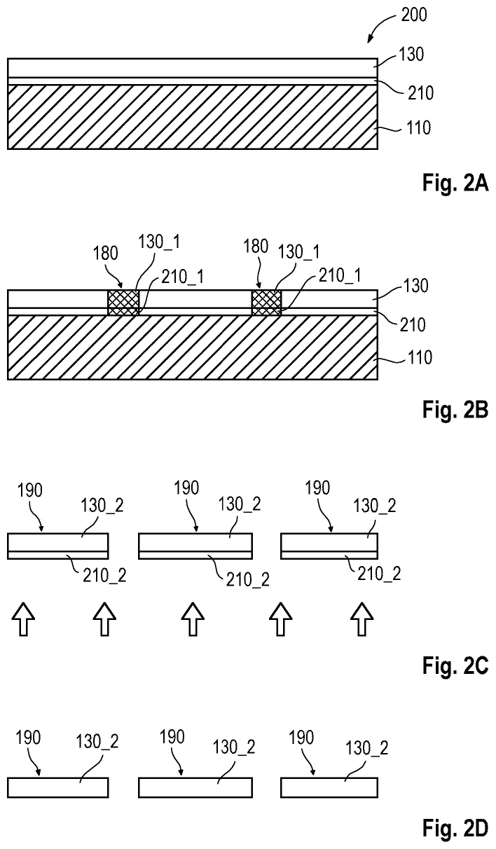

The carrier (not shown in FIG. 2D) may stabilize the semiconductor substrate 100 during thinning (e.g. optional back grinding and etching) and chip separation by etching. Further, the carrier (not shown) allows handling of the semiconductor chips 190 after being separated. The carrier may, e.g., be a temporary carrier in which case the joining between the semiconductor device layer 130 and the carrier is a reversible (releasable) connection.

FIG. 2A illustrates a semiconductor substrate 200. The semiconductor substrate 200 includes the semiconductor substrate layer 110, the semiconductor device layer 130 and an etch stop layer 210 arranged between the semiconductor substrate layer 110 and the semiconductor device layer 130. Except of the etch stop layer 210, the semiconductor substrate 200 may be identical to the semiconductor substrate 100, and reference is made to the above description in order to avoid reiteration.

The semiconductor etch stop layer 210 may, e.g., be an epitaxial layer.

Referring to FIG. 2B, the dicing areas 180 are formed by transforming the areas 130_1 of the semiconductor device layer 130 and areas 210_1 of the semiconductor etch stop layer 210 into the dicing areas 180. Differently put, the areas 210_1 of the etch stop layer 210 form a part of the dicing areas 180. In view of the transformation process and other characteristics and features of the semiconductor substrate 200 illustrated in FIG. 2B, reference is made to above description in conjunction with FIG. 1B.

FIG. 2C illustrates the combined process of removing the semiconductor substrate layer 110 and separating the semiconductor chips 190 by etching. By virtue of the etch stop layer 210, the areas 130_2 of the semiconductor device layer 130 are protected against etching. Hence, given an anisotropic etching process is used, the semiconductor device layer material may not need to be resistant against etching as is the case in the example of FIG. 1C. That is, if an anisotropic dopant-selective chemical etching process is used, the semiconductor device layer 130 shown in FIGS. 2A-2D can have a higher doping density than in the example of FIGS. 1A-2C. A slight side wall etching of the semiconductor chips 190 may occur.

Apart from the differences caused by the etch stop layer 210, the processes, characteristics and handling options of the semiconductor chips 190 of FIG. 2C may be identical to the corresponding disclosure in the context of FIG. 1C, and reference is made to the corresponding description to avoid reiteration.

FIG. 2D illustrates the (optional) removal of the areas 210_2 of the etch stop layer 210 from the semiconductor chips 190 after chip separation.

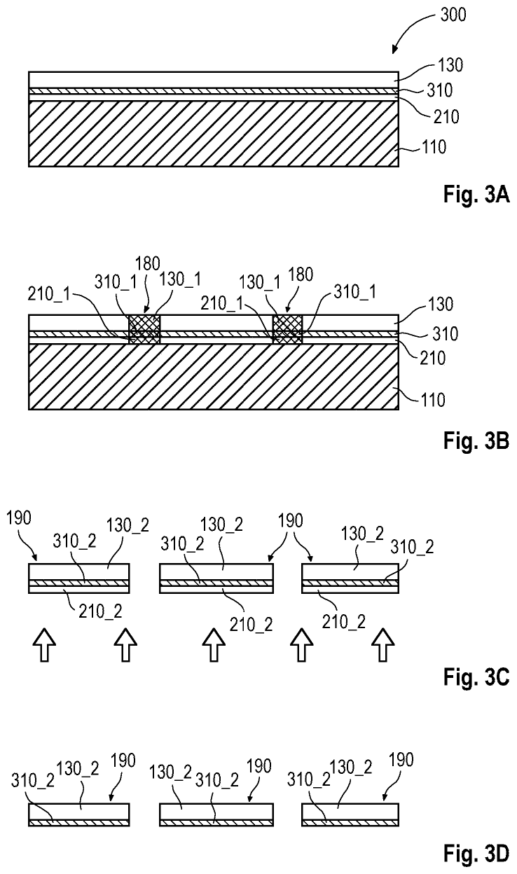

Semiconductor substrate 300, as shown in FIG. 3A, may be identical to semiconductor substrate 200 except that a semiconductor contact layer 310 is arranged between the semiconductor device layer 130 and the etch stop layer 210. The semiconductor contact layer 310 may be an electrically conducting layer destined to serve as a backside electrical contact of the semiconductor chip 190 after dicing. If the etch stop layer 210 is omitted (see, e.g., FIGS. 1A through 1C), the semiconductor contact layer 310 may be arranged between the semiconductor device layer 130 and the semiconductor substrate layer 110.

Referring to FIG. 3B, reference is made to the description of FIG. 2B except that an area 310_1 of the semiconductor contact layer 310 additionally forms a part of the dicing area 180. If the material of semiconductor contact layer 310 is intrinsically etchable, a transformation of this layer into an etchable area 310_1 is not necessarily needed. However, in many cases the preparation of the dicing area 180 may also include a transformation of the areas 310_1 of the semiconductor contact layer. In view of all other features, characteristics or processes, reference is made to the description in conjunction with FIGS. 1B and 2B.

FIG. 3C illustrates the chip separation process. The chip separation process is done by etching to remove the (e.g. residual) semiconductor substrate layer 110 and to separate the semiconductor chips 190, as has been described before in conjunction with FIGS. 1C and 2C. A slight side wall etching of contact layer 310 and possibly also of the semiconductor device layer 130 of the semiconductor chips 190 may occur.

Referring to FIG. 3D, the semiconductor chips 190 are provided with an area 310_2 of the semiconductor contact layer 310. This area 310_2 of the semiconductor contact layer 310 may serve as a backside electrical contact of the semiconductor chip 190. For instance, a backside metal electrode (not shown) may be applied to the area 310_2 of the semiconductor contact layer 310.

FIGS. 4A-4D illustrate features and process variants with reference to a semiconductor substrate 400, which can be applied to all processes and semiconductor substrates 100, 200, 300 described before. More specifically, the semiconductor substrate 400 comprises a substrate layer 110 and areas 130_2 of a semiconductor device layer 130. The areas 130_1 of the semiconductor device layer 130, which can be removed by etching, are provided in the dicing areas 180.

Integrated devices may be provided in the areas 130_2 of the semiconductor device layer 130. In the example shown in FIG. 4A, a transistor may be implemented. By way of example, the integrated device may comprise a gate pad 414, a source pad 416 and a polymer material (e.g. imide) 418 partly covering the gate pad 414 and the source pad 416.

Further, an inert layer 412 may have been generated over the transformed areas 130_1 of the semiconductor device layer 130 to cover the dicing areas 180 at the front side of the semiconductor substrate 400 (e.g. wafer). The inert layer 412 may, e.g., comprise or be of an oxide, a nitride, an intrinsic (undoped) polycrystalline silicon, an organic material or a metal. In some cases, the inert layer 412 may be a hard passivation layer. The inert layer 412 may be structured as shown in FIG. 4A. The inert layer 412 is resistant against etching, i.e. may act as a structured front side etch stop layer.

Referring to FIG. 4B, the e.g. fully processed semiconductor substrate 400 may then be mounted on a carrier 420 with the semiconductor device layer 130 (which may already be structured to be composed of the areas 130_1 and 130_2) facing the carrier 420. For instance, the carrier 420 may be connected to the semiconductor substrate 400 by an adhesive layer 430. The adhesive layer 430 may allow the carrier 420 to be a temporary carrier by having the property to release the carrier 420 from the semiconductor substrate 400. The carrier release may, e.g., be carried out by application of energy.

The carrier 420 may comprise or be of a mechanically rigid material configured to support the semiconductor substrate 400 during subsequent processing. For instance, the carrier 420 may comprise or be of glass. The carrier 420 may also be a semiconductor carrier, e.g. a wafer.

In the following description the process of removing the semiconductor substrate layer 110 and the dicing areas 180 is described by exemplarily using chemical etching. Chemical etching, generally, may comprise wet chemical etching and dry chemical etching (e.g. plasma assisted chemical etching). Without loss of generality, the following description relates to applying a wet chemical etchant.

Further, the etching process exemplified below relies on dopant-selective etching. In dopant-selective etching, the etching rate strongly depends on the doping density of the semiconductor material. Features, processes and characteristics described below in the context of dopant-selective chemical etching are disclosed herein to apply to all embodiments described herein. However, in general, other etching mechanisms may also be feasible.

The semiconductor substrate layer 110 may be a high-doped semiconductor layer have a doping density which is, e.g., in a range between 5×10¹⁸ cm⁻³ to 3×10²⁰ cm⁻³, in particular equal to or greater than 10¹⁹ cm⁻³. In particular, the doping density may be in a range of 1-5×10¹⁹ cm⁻³ or, e.g., 3-4×10¹⁹ cm⁻³. The semiconductor substrate layer 110 may be doped with boron, arsenic or phosphorus. In some applications arsenic may be advantageous as a dopant since it diffuses less and sharper doping profiles can be obtained. The high-doped semiconductor substrate layer 110 may, e.g., have a thickness between about 500 μm and 1000 μm.

The semiconductor device layer 130 may have a doping density of equal to or less than 10¹⁸ cm⁻³, 5×10¹⁷ cm⁻³, or 10¹⁷ cm⁻³. The semiconductor device layer 130 may, e.g., be doped with boron, arsenic, phosphorus, or antimony. Generally, the dopant of the semiconductor device layer 130 may be the same as the dopant of the semiconductor substrate layer 110 or a different one. Further, the semiconductor device layer 130 may have different doping levels and/or materials in different depths or different areas of the semiconductor device layer 130, i.e. may be structured in terms of doping levels and/or doping materials and/or doping depths and/or doping areas. The semiconductor device layer 130 may be an epitaxial layer.

Referring to FIG. 4C, the high-doped semiconductor substrate layer 110 of the device semiconductor substrate 400 may then be partially removed by, e.g., grinding. A thickness of, e.g., 600-1000 μm of the high-doped semiconductor substrate layer 110 may be removed. The partial removal may stop at about 5-60 μm, in particular 5-15 μm or 5-10 μm remaining thickness of the high-doped semiconductor substrate layer 110 for subsequent wet chemical removal. The total thickness variation (TTV) after the partial removal (e.g. grinding) process may, for example, be 2-3 μm on, e.g., a 200 mm wafer. For some devices, and especially if ultra-thin semiconductor chips 190 are to be produced, this TTV may be too high.

Referring to FIG. 4D, the remainder of the high-doped semiconductor substrate layer 110 may then be completely removed by dopant-selective chemical etching. The removal by dopant-selective chemical etching may remove, e.g., a thickness between 5-60 μm, in particular 5-15 μm or 5-10 μm of the remainder of the high-doped semiconductor substrate layer 110 and, in addition, the dicing areas 180. In the example shown in FIG. 4D the dopant-selective chemical etching stops at the areas 130_2 of the low-doped semiconductor device layer 130. In other examples, see e.g. FIGS. 2A-2D and FIGS. 3A-3D, the dopant-selective chemical etching may stop at the semiconductor etch stop layer 210 (or, more specifically, at the non-transformed areas 210_2 of the semiconductor etch stop layer 210). The semiconductor etch stop layer 210 may be an epitaxial layer.

As already mentioned above, the dicing areas 180 are removed in the course of the etching process to provide for chip separation. The inert layer 412 protects the adhesive layer 430 and/or the carrier 420 and e.g. also the front side of the semiconductor chips 190 from being exposed to the etchant.

For the dopant-selective chemical etching process, a dopant-selective wet chemical solution may be used, which will etch the remainder of the high-doped semiconductor substrate layer 110 quickly at, e.g., a rate of 3-50 μm/min. The dopant-selective chemical etching process will stop at the low-doped semiconductor etch stop layer 210 before reaching the e.g. high-doped semiconductor device layer 130 or, if no low-doped semiconductor etch stop layer 210 is present, will stop at the areas 130_2 of the low-doped semiconductor device layer 130.

A dopant-selective etchant such as an etchant including R—COOH could be used. The R component may include an alkyl group such as, e.g., a methyl or an ethyl or a propyl. The etchant may be a mixture comprising R—COOH, hydrofluoric acid (HF) and nitric acid (HNO₃). As an example, HNA may be used. HNA is a mixture of HF, HNO₃, acetic acid (CH₃COOH) and water. A typical concentration may be HF at 10 wt %, HNO₃ at 20 wt %, and CH₃COOH at 50 wt %. The HNA mixture etches high-doped silicon quickly, e.g. with an etch rate of 20-40 μm/min. Low-doped materials are etched very slowly, e.g. at a rate of about 0.2 μm/min or less. Thereby, the etchant removes the high-doped substrate layer 110 and with it all roughness and inhomogeneity brought in by the (optional) initial grinding process. Further, the etchant separates the semiconductor chips 190. Chip separation by etching minimizes hairline-cracks at the edges of the semiconductor chips 190.

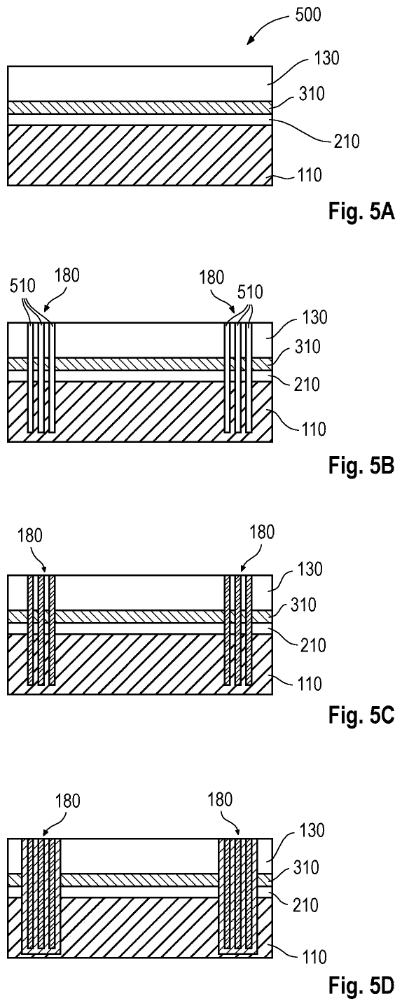

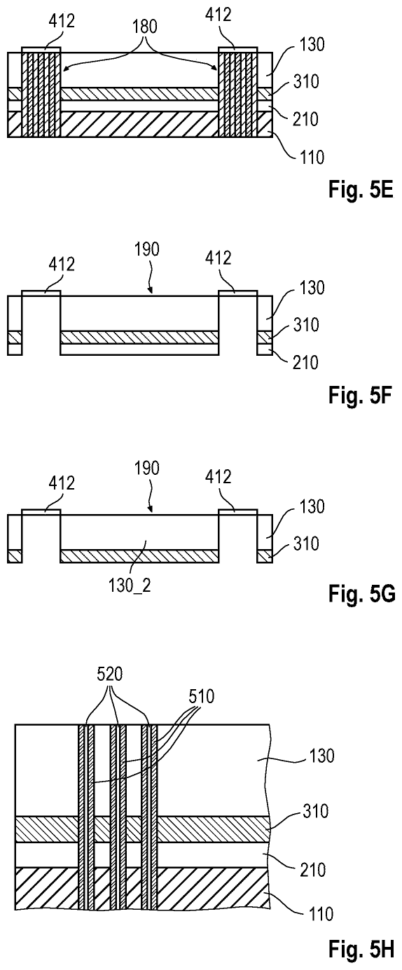

FIGS. 5A-5G illustrate stages of an exemplary process of manufacturing a semiconductor device by forming high-doped dicing areas 180 in the semiconductor device layer 130. The process relies on depositing a dopant into the dicing areas by dopant diffusion.

In FIG. 5A a semiconductor substrate 500 including a substrate layer 110, an etch stop layer 210 and a semiconductor device layer 130 is shown. Further, the semiconductor substrate 500 may include an optional semiconductor contact layer 310 arranged between the (optional) semiconductor etch stop layer 210 and the semiconductor device layer 130. Reference is made to the description of FIGS. 3A-3D in which the semiconductor contact layer 310 has already been described.

The doping density of the low-doped semiconductor etch stop layer 210 may, e.g., be equal to or less than 10¹⁷ cm⁻³, or 10¹⁶ cm⁻³, or 10¹⁵ cm⁻³, or 10¹⁴ cm⁻³. The low-doped semiconductor etch stop layer 210 may be an epitaxial layer. It may, e.g., have a layer thickness of 200 nm to 10 μm, in particular 1-6 μm. It is specifically to be noted that very thin etch stop layers 210 having a thickness of equal to or less than 1000 nm, 800 nm, 600 nm, or 400 nm are feasible.

Referring to FIG. 5B one or more trenches 510 are generated in the dicing areas 180. The generation of trenches 510 may be performed before, during or after the FEOL processing.

Referring to FIG. 5C, the trenches 510 may then be filled with a high-doped filler material. For example, the trenches 510 may be filled with high-doped polycrystalline silicon. Filling may comprise a partial fill or a complete fill of the trenches 510.

Referring to FIG. 5D, the dopant in the high-doped filler material is allowed to diffuse out into the dicing area 180. The diffusion process may either be carried out by specific annealing or may be a process which automatically occurs e.g. during FEOL processing. The diffusion causes the entire dicing area 180 to be highly doped and thus susceptible to dopant-selective chemical etching.

Referring to FIG. 5E, the dicing areas 180 (i.e. kerf regions) are optionally covered by an inert layer 412. Further, FIG. 5E illustrates partial removal of the substrate layer 110, e.g. by grinding.

FIG. 5F illustrates chemical etching to completely remove the substrate layer 110 and to separate the semiconductor chips 190. As mentioned above, dopant-selective side wall etching may occur.

FIG. 5G illustrates the removal of the etch stop layer 210. Removal of the etch stop layer 210 may comprise isotropic etching and/or polishing. The removal of the etch stop layer 210 exposes the semiconductor contact layer 310. That way, the semiconductor chip 190 is equipped with an electrically conductive backside layer. The electrically conductive backside layer may, e.g., act as a contact layer to a backside electrode of the semiconductor chip 190, e.g. a load electrode (e.g. drain electrode or source electrode) of a power integrated device.

FIG. 5H illustrates a detail of FIG. 5C. FIG. 5H illustrates an incomplete fill of the trenches 510 in which a core section of the trenches may remain unfilled to form a void 520.

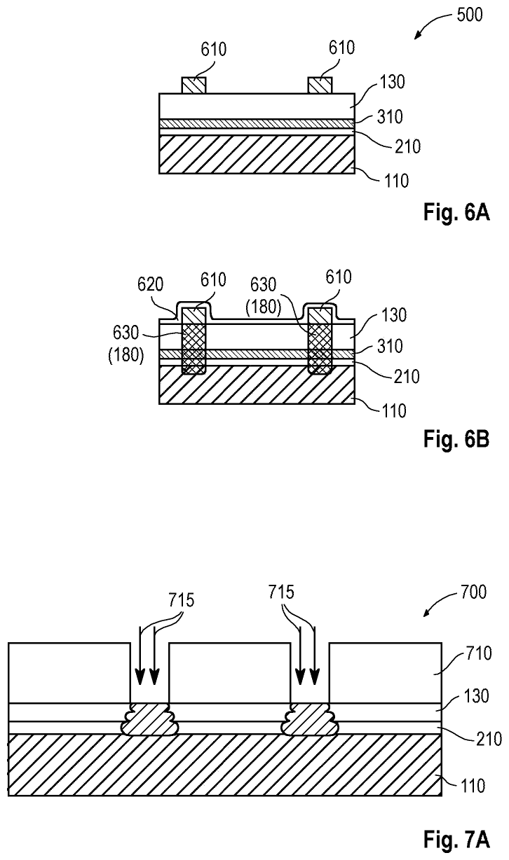

FIGS. 6A-6B illustrates a variant of the process described in conjunction with FIGS. 5A-5H. The process shown in FIGS. 6A-6B also relies on depositing a dopant into the dicing areas 180 by dopant diffusion. However, the dopant donator is not introduced into trenches but placed atop the dicing areas 180 (kerf regions).

More specifically, high-doped dopant donator structures 610 are formed atop each of the dicing areas 180 as shown in FIG. 6A (instead of filling trenches 510 by a dopant donator as shown in FIG. 5C). The dopant in the high-doped dopant donator structures 610 is then allowed to diffuse out into the dicing areas 180. The corresponding dopant diffusion region 630 is shown in FIG. 6B. The dopant diffusion region 630 transforms the areas of the semiconductor device layer 130 and, if present, the optional semiconductor contact layer 310 and/or the optional etch stop layer 210 into dicing areas which can be removed by dopant-selective chemical etching.

The diffusion process may be carried out by annealing. Further, an insulating layer 620 such as, e.g., a hard passivation layer (e.g. oxide or nitride or oxide/nitride layer) may be deposited over semiconductor device layer 130 and the high-doped dopant donator structures 610 before annealing.

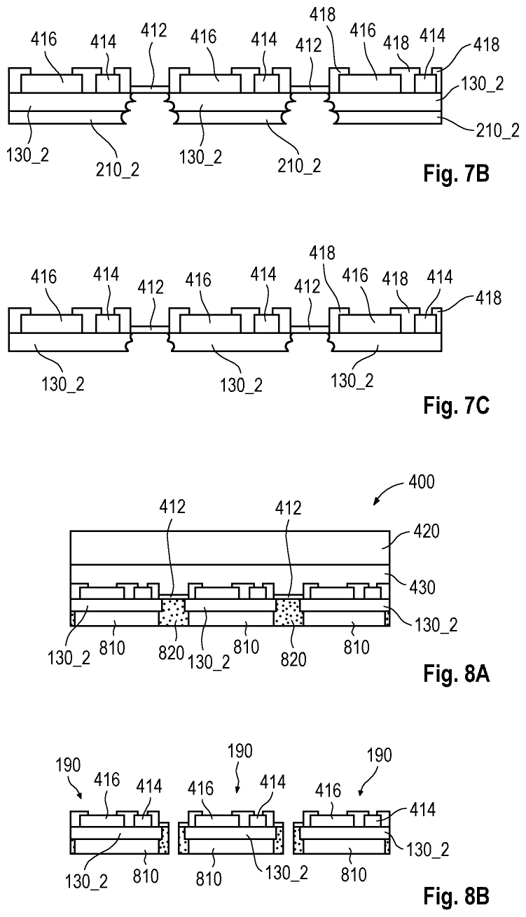

Another example of forming high-doped dicing areas 180 in the semiconductor device layer 130 is illustrated in FIGS. 7A-7C. Referring to FIG. 7A, a photoresist layer 710 may be deposited and structured in accordance with the desired kerf pattern. Optionally, an additional oxide layer (not shown) may have been applied before and structured in accordance with the photoresist layer 710. That way, the dicing areas 180 of the semiconductor substrate 700 are exposed.

The dopant is then deposited into the dicing areas 180 by a dopant implantation process. The implantation of the dopant is indicated by arrows 715. A high implant dose may be used to obtain the required doping density in the dicing areas 180. As shown in FIG. 7A, multiple dopant implant steps may be carried out with different energies to make sure that the dicing area 180 has a sufficient high doping density across its entire depth. Further, as apparent from FIG. 7A, the dopant implantation may not only transform the semiconductor device layer 130 but also the etch stop layer 210 (if present) for being removed by the subsequent dopant-selective etching process. Although not shown in FIG. 7A, the semiconductor substrate 700 may additionally be equipped with the semiconductor contact layer 310 (see FIGS. 3A-3C, 5A-5G, 6) which may, optionally, also be transformed into a high-doped kerf area 310_1.

Referring to FIG. 7B, the substrate layer 110 and the high-doped dicing area 180 are removed by dopant-selective etching, while the low-doped areas 210_2 of the etch stop layer are maintained. As can be seen in FIG. 7B, the semiconductor device layer 130 may, e.g., have a multi-curved cross-sectional shape indicative of multiple dopant implant processes. In general, the use of one or more implant processes for kerf doping allows to shape edge regions of the semiconductor device layer 130 (i.e. the edges of the semiconductor chips 190) with a high degree of design variability.

Referring to FIG. 7C, the low-doped area 210_2 of the etch stop layer 210_1 may then be removed by isotropic etching and/or polishing. During this process also the kerf region (i.e. the dicing area 180) is slightly etched. The multi-curved cross-sectional shape of the dicing edge of the area 130_2 of the semiconductor device layer 130 may be slightly rounded or leveled (see, e.g., FIGS. 10, 11). Nevertheless, the edges of the semiconductor chips 190 maintain their characteristic shape determined by the fabrication process as described herein.

The embodiments shown in FIGS. 5A-5G and 7A-7C are examples of transforming areas of the semiconductor device layer 130 into dicing areas (kerf) which can be removed by etching. Although not depicted in FIGS. 5A-5G and 7A-7C, both embodiments may use the concept of connecting the front side of the semiconductor substrate 500, 700 to a carrier 420 during processing. For instance, the semiconductor substrate 500 may be joined to a carrier 420 after trench filling (FIG. 5C) and the semiconductor substrate 700 may be joined to a carrier 420 after dopant implant (FIG. 7A) and removal of the photoresist layer 710.

FIGS. 8A-8B illustrate a first example of further processing the semiconductor substrate after removing the dicing areas 180. For example, the semiconductor substrate 400 is exemplarily used for the following disclosure, while the other semiconductor substrates 100-300, 500, 700 could likewise be processed in the manner described below.

FIG. 8A illustrates a backside metallization of the semiconductor substrate 400. During the backside metallization process a metal layer 810 is applied. Optionally, the kerf (former dicing areas 180) may be filled by a kerf filler material 820. The kerf filler material 820 may be a polymer material, e.g. epoxy resin. The metal layer 810 may be a structured metal layer which covers the backsides of the semiconductor chips 190. The metal layer 810 may be shaped not to overlay the kerf (former dicing areas 180).

Referring to FIG. 8B, the semiconductor chips 190 are demounted (released) from the carrier 420 e.g. by activating (e.g. chemically modifying) the releasable adhesive 430. The final chip separation may then be carried out by cutting through the kerf filler material 820. This cutting process may be performed by laser cutting.

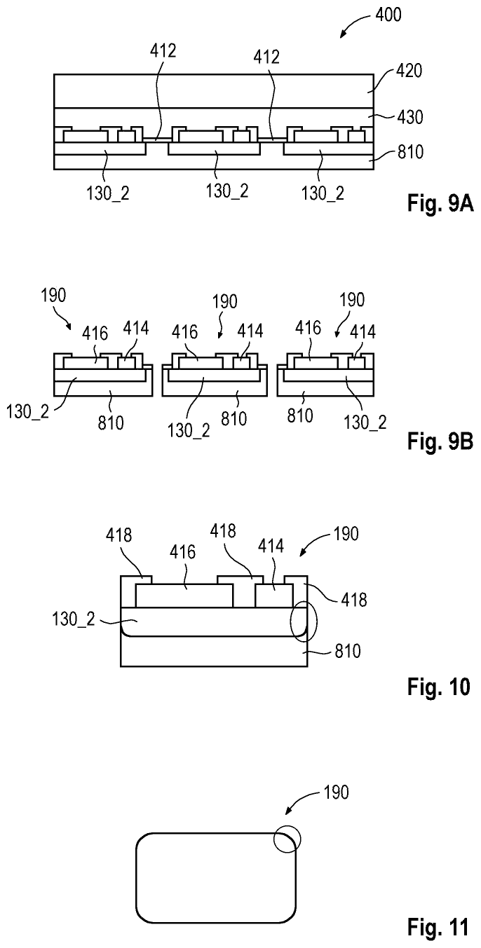

FIGS. 9A-9B illustrate a second example of further processing the semiconductor substrate 400 after removal of the dicing areas 180. Here, the entire backside of the semiconductor substrate 400 including the kerf region (former dicing areas 180) is metallized. Metallization includes depositing a metal layer 810 both over the backsides of the areas 130_2 of the semiconductor device layer 130 and in the kerf region.

FIG. 9B illustrates the cutting step through the metal material of the metal layer 810 filling the kerf region. The cutting results in final chip separation.

While the semiconductor chips 190 in FIG. 8B are provided with a polymer side wall protection layer, the semiconductor chips 190 in FIG. 9B are provided with a metal side wall layer.

Referring to FIG. 10, an exemplary semiconductor device containing a semiconductor chip 190 may have rounded semiconductor chip edges in a vertical dimension. Alternatively or additionally, as shown in FIG. 11, an exemplary semiconductor device containing a semiconductor chip 190 may have rounded semiconductor chip edges in a horizontal dimension. These and other designs of the chip edge can be freely selected by adapting the doping profile in the kerf in a corresponding manner. This can reduce the occurrence of hairline-cracks at the edges of the semiconductor chips 190.

In general, the concept of chip separation by combined substrate and kerf etching as disclosed herein allows to reduce the width of the kerf region so that a larger proportion of the wafer surface can be utilized. Further, process costs can be reduced compared to standard DBG chip separation processes.

The following examples pertain to further aspects of the disclosure:

Example 1 is a method of manufacturing a semiconductor device, the method comprising providing a semiconductor substrate comprising a semiconductor substrate layer, and a semiconductor device layer; transforming areas of the semiconductor device layer into dicing areas which can be removed by etching; and removing the semiconductor substrate layer and the dicing areas by using etching.

In Example 2, the subject matter of Example 1 can optionally include wherein transforming comprises depositing a dopant into the dicing areas.

In Example 3, the subject matter of Example 2 can optionally include depositing the dopant into the dicing areas by dopant implantation.

In Example 4, the subject matter of Example 2 can optionally include depositing the dopant into the dicing areas by dopant diffusion.

In Example 5, the subject matter of Example 4 can optionally include wherein depositing the dopant into the dicing areas by dopant diffusion comprises: generating one or more trenches in each of the dicing areas; filling the one or more trenches of a dicing area with a high-doped filler material; and allowing the dopant in the high-doped filler material to diffuse out into the dicing area.

In Example 6, the subject matter of Example 4 can optionally include wherein depositing the dopant into the dicing areas by dopant diffusion comprises: forming a high-doped dopant donator structure atop each of the dicing areas; and allowing the dopant in the high-doped dopant donator structure to diffuse out into the dicing area.

In Example 7, the subject matter of any preceding Example can optionally include wherein the semiconductor substrate layer is a high-doped layer.

In Example 8, the subject matter of any preceding Example can optionally include wherein etching is dopant-selective chemical etching.

In Example 9, the subject matter of any preceding Example can optionally include wherein the semiconductor substrate further comprises a semiconductor etch stop layer arranged between the semiconductor substrate layer and the semiconductor device layer.

In Example 10, the subject matter of Example 9 can optionally include transforming areas of the semiconductor etch stop layer to form part of the dicing areas which can be removed by etching.

In Example 11, the subject matter of Example 9 or 10 can optionally include wherein the semiconductor etch stop layer is a low-doped semiconductor layer.

In Example 12, the subject matter of any of Examples 9 to 11 can optionally include wherein the semiconductor substrate further comprises a semiconductor contact layer arranged between the semiconductor etch stop layer and the semiconductor device layer.

In Example 13, the subject matter of any preceding Example can optionally include generating a structured front side etch stop layer over the semiconductor device layer to cover the dicing areas.

In Example 14, the subject matter of Example 13 can optionally include wherein the structured front side etch stop layer comprises a hard passivation dielectric material or a polymer material or a metal.

In Example 15, the subject matter of any preceding Example can optionally include processing the semiconductor substrate to form integrated devices in the semiconductor device layer; and thereafter mounting the semiconductor substrate on a carrier with the semiconductor device layer facing the carrier.

In Example 16, the subject matter of Example 15 can optionally include wherein processing the semiconductor substrate is done after transforming the areas of the semiconductor device layer into dicing areas.

In Example 17, the subject matter of Example 15 or 16 can optionally include wherein removing the semiconductor substrate layer and the dicing areas by using etching is done after mounting the semiconductor substrate on a carrier.

In Example 18, the subject matter of any preceding Example can optionally include wherein removing the semiconductor substrate layer and the dicing areas comprises: partially removing the semiconductor substrate layer by grinding; followed by completely removing the residual semiconductor substrate layer and the dicing areas by etching.

Example 19 is a semiconductor device including a semiconductor device chip, the semiconductor device chip including: a semiconductor device layer comprising an integrated device, wherein a dicing edge of the semiconductor device layer has been formed by dopant-selective chemical etching.

In Example 20, the subject matter of Example 19 can optionally include wherein the dicing edge of the semiconductor device layer has a multi-curved cross-sectional shape indicative of multiple dopant implant processes.

In Example 21, the subject matter of Example 19 or 20 can optionally include a metal support layer supporting the semiconductor device layer, wherein the metal support layer provides a side wall protection of the semiconductor device layer.

In Example 22, the subject matter of Examples 19 or 20 can optionally include a metal support layer supporting the semiconductor device layer; and a side wall protection of the semiconductor device layer comprising a polymer material.

In Example 23, the subject matter of any of Examples 19 to 22 can optionally include wherein a thickness of the semiconductor device layer is equal to or less than 60 μm or 50 μm or 40 μm or 30 μm or 20 μm or 15 μm.

In Example 24, the subject matter of any of Examples 19 to 23 can optionally include wherein the integrated device comprises a power device.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of manufacturing a semiconductor device, the method comprising:
providing a semiconductor substrate comprising a semiconductor substrate layer and a semiconductor device layer;
transforming areas of the semiconductor device layer into dicing areas which can be removed by etching; and
removing the semiconductor substrate layer and the dicing areas by using etching.

2. The method of claim 1, wherein the transforming comprises:
depositing a dopant into the dicing areas.

3. The method of claim 2, wherein depositing the dopant into the dicing areas comprises:
depositing the dopant into the dicing areas by dopant implantation.

4. The method of claim 2, wherein depositing the dopant into the dicing areas comprises:
depositing the dopant into the dicing areas by dopant diffusion.

5. The method of claim 4, wherein depositing the dopant into the dicing areas by dopant diffusion comprises:
generating one or more trenches in each of the dicing areas;
filling the one or more trenches of a dicing area with a high-doped filler material; and
allowing the dopant in the high-doped filler material to diffuse out into the dicing area.

6. The method of claim 4, wherein depositing the dopant into the dicing areas by dopant diffusion comprises:
forming a high-doped dopant donator structure atop each of the dicing areas; and
allowing the dopant in the high-doped dopant donator structure to diffuse out into the dicing area.

7. The method of claim 1, wherein the semiconductor substrate layer is a high-doped layer.

8. The method of claim 1, wherein the etching is dopant-selective chemical etching.

9. The method of claim 1, wherein the semiconductor substrate further comprises a semiconductor etch stop layer arranged between the semiconductor substrate layer and the semiconductor device layer.

10. The method of claim 9, further comprising:
transforming areas of the semiconductor etch stop layer to form part of the dicing areas which can be removed by etching.

11. The method of claim 9, wherein the semiconductor etch stop layer is a low-doped semiconductor layer.

12. The method of claim 9, wherein the semiconductor substrate further comprises a semiconductor contact layer arranged between the semiconductor etch stop layer and the semiconductor device layer.

13. The method of claim 1, further comprising:
generating a structured front side etch stop layer over the semiconductor device layer to cover the dicing areas.

14. The method of claim 13, wherein the structured front side etch stop layer comprises a hard passivation dielectric material or a polymer material or a metal.

15. The method of claim 1, further comprising:
processing the semiconductor substrate to form integrated devices in the semiconductor device layer; and
thereafter mounting the semiconductor substrate on a carrier with the semiconductor device layer facing the carrier.

16. The method of claim 15, wherein processing the semiconductor substrate is done after transforming the areas of the semiconductor device layer into dicing areas.

17. The method of claim 15, wherein removing the semiconductor substrate layer and the dicing areas by using the etching is done after mounting the semiconductor substrate on the carrier.

18. The method of claim 1, wherein removing the semiconductor substrate layer and the dicing areas comprises:
partially removing the semiconductor substrate layer by grinding such that a residual semiconductor substrate layer remains; and
thereafter completely removing the residual semiconductor substrate layer and the dicing areas by using the etching.

19. A semiconductor device including a semiconductor device chip, the semiconductor device chip comprising:
a semiconductor device layer comprising an integrated device, wherein a dicing edge of the semiconductor device layer has been formed by dopant-selective chemical etching.

20. The semiconductor device of claim 19, wherein the dicing edge of the semiconductor device layer has a multi-curved cross-sectional shape indicative of multiple dopant implant processes.

21. The semiconductor device of claim 19, further comprising:
a metal support layer supporting the semiconductor device layer, wherein the metal support layer provides a side wall protection of the semiconductor device layer.

22. The semiconductor device of claim 19, further comprising:
a metal support layer supporting the semiconductor device layer; and
a side wall protection of the semiconductor device layer comprising a polymer material.

23. The semiconductor device of claim 19, wherein a thickness of the semiconductor device layer is equal to or less than 60 μm or 50 μm or 40 μm or 30 μm or 20 μm or 15 μm.

24. The semiconductor device of claim 19, wherein the integrated device comprises a power device.
